(19) United States
(12) Patent Application Publication
(10) Pub. No.: US 2014/0319475 A1
(43) Pub. Date: Oct. 30, 2014

(54) ORGANIC LIGHT EMITTING DIODE DISPLAY AND MANUFACTURING METHOD THEREOF

(71) Applicant: Samsung Display Co., Ltd., Yongin-City (KR)

(72) Inventors: Sung-Joong Joo, Yongin-city (KR); You-Min Cha, Yongin-city (KR)

(73) Assignee: Samsung Display Co., Ltd., Yongin-city (KR)

(21) Appl. No.: 14/035,058

(22) Filed: Sep. 24, 2013

(30) Foreign Application Priority Data
Apr. 25, 2013 (KR) 10-2013-0046360

(51) Int. Cl. H01L 27/32

(52) U.S. Cl. CPC H01L 27/32
USPC 257/40; 438/34

(57) ABSTRACT

An organic light emitting diode display is disclosed. In one aspect, the display includes a pixel electrode formed on a substrate and a pixel defining layer on the pixel electrode, the pixel defining layer having an opening exposing a part of the pixel electrode, and a stepped side wall of the opening. The display also includes an organic emission layer on the pixel electrode in the opening of the pixel defining layer and a common electrode covering the organic emission layer and the pixel defining layer. The pixel defining layer has a stepped side wall of the opening.

### RELATED APPLICATIONS

This application claims priority to and the benefit of Korean Patent Application No. 10-2013-0046360 filed in the Korean Intellectual Property Office on Apr. 25, 2013, the entire contents of which are incorporated herein by reference.

### BACKGROUND

1. Field

The described technology generally relates to an organic light emitting diode display, and more particularly, to an organic light emitting diode display including a pixel defining layer and a manufacturing method thereof.

2. Description of the Related Technology

An organic light emitting diode (OLED) display includes a plurality of pixels, and a pixel circuit and an OLED are positioned in each pixel. Each pixel is surrounded by a pixel defining layer to be separated from adjacent pixels. The OLED generally includes a pixel electrode separately formed for each pixel, an organic emission layer formed on the pixel electrode, and a common electrode covering the plurality of organic emission layers and the pixel defining layer.

The organic emission layer may be formed by a printing method. The printing method is a method of storing a solution including an organic material and a solvent in an ejecting head and ejecting droplets of the solution on the pixel electrode through nozzles installed in the ejecting head. The ejected solution is trapped in an opening of the pixel defining layer and while the solvent is evaporated, the organic emission layer is formed.

However, when the solvent is evaporated from the ejected solution, the solvent is evaporated under different conditions at a portion close to the pixel defining layer and a portion far away from the pixel defining layer due to a thickness of the pixel defining layer. Accordingly, the organic emission layer has a non-uniform thickness, and when the organic emission layers are multi-layered, the non-uniformity of the thickness deteriorates. As a result, when the pixel emits light, central luminance and edge luminance may be different from each other.

The above information disclosed in this Background section is only for enhancement of understanding of the background of the described technology and therefore it may contain information that does not form the prior art that is already known in this country to a person of ordinary skill in the art.

### SUMMARY

One inventive aspect is an OLED display and a manufacturing method thereof having advantages of increasing thickness uniformity of an organic emission layer and as a result, increasing light emission uniformity of a pixel.

Another aspect is an OLED display, including: a pixel electrode a substrate; a pixel defining layer on the pixel electrode, the pixel defining layer having an opening exposing a part of the pixel electrode, and a stepped side wall of the opening; an organic emission layer the pixel electrode in the opening of the pixel defining layer; and a common electrode covering the organic emission layer and the pixel defining layer. The pixel defining layer may have a stepped side wall of the opening.

The pixel defining layer may be configured by a plurality of layers having openings having different widths, and the plurality of layers may have an opening having a larger width as the plurality of layers is far away from the pixel electrode. Each of the plurality of layers may comprise the same insulating material, and have the same thickness.

The organic emission layer may be formed by a printing method, and configured by a plurality of layers corresponding to at least two layers among the plurality of layers configuring the pixel defining layer. A thickness of each of the plurality of layers configuring the pixel defining layer may be smaller than a thickness of each of the plurality of layers configuring the organic emission layer.

The pixel defining layer may include a first layer having a first opening, and a second layer formed on the first layer and having a second opening. The organic emission layer may include a first layer having a larger height of the upper surface than a height of the first layer of the pixel defining layer, and a second layer having a larger height of the upper surface than a height of the second layer of the pixel defining layer. The organic emission layer may have the same width as the first opening.

Further, the pixel defining layer may include a first layer having a first opening, and a second layer formed on the first layer and having a second opening. In addition, the organic emission layer may include a first layer filling the first opening and covering the first layer of the pixel defining layer, and a second layer filling the second opening and covering the second layer of the pixel defining layer.

The OLED display may further include a light blocking layer formed directly on the organic emission layer and the pixel defining layer. The light blocking layer may have an opening exposing a central portion of the organic emission layer.

Another aspect is a manufacturing method of an OLED display, including: forming a buffer layer and a pixel circuit on a substrate; and forming a pixel electrode on a planarization layer covering the pixel circuit; and forming a pixel defining layer by laminating a first layer having a first opening, a second layer having a second opening having a larger width than the first opening, and a third layer having a third opening having a larger width than the second opening, on the pixel electrode. Further, the manufacturing method of an OLED display may include forming a first layer of the organic emission layer by ejecting a printing solution into the first opening and then evaporating a solvent and forming a second layer of the organic emission layer by ejecting the printing solution into the second opening and evaporating the solvent; and forming a common electrode on the organic emission layer and the pixel defining layer.

A side wall of the first opening, a side wall of the second opening, and a side wall of the third opening may be vertical side walls, and the first layer, the second layer, and the third layer of the pixel defining layer may be formed with the same thickness. The printing solution ejected into the first opening may cover the first layer of the pixel defining layer along an edge, and the printing solution ejected into the second opening may cover the second layer of the pixel defining layer along an edge.

The manufacturing method of an OLED display may further include removing an outer portion of the organic emission layer by etching before forming the common electrode. A width of the organic emission layer may be the same as or larger than the width of the first opening.

Further, the manufacturing method of an OLED display may further include forming a light blocking layer on the organic emission layer and the pixel defining layer before forming the common electrode. The light blocking layer may have an opening exposing the central portion of the organic emission layer. A width of the opening of the light blocking layer may be the same as the width of the first opening.

According to at least one of the disclosed embodiments, it is possible to increase thickness uniformity of an organic emission layer formed by a printing method. The OLED display is suitable for mass production, and it is possible to improve a display characteristic by increasing light emission uniformity of each pixel. Further, since there is no large modification in other constituent elements except for a pixel defining layer as compared with a manufacturing process in the related art, it is possible to easily manufacture the OLED display by using existing manufacturing equipment.

### BRIEF DESCRIPTION OF THE DRAWINGS

FIGS. 1A to 1F are cross-sectional views sequentially illustrating a manufacturing method of an OLED display according to a first exemplary embodiment.

FIGS. 2A and 2B are cross-sectional views sequentially illustrating a manufacturing method of an OLED display according to a second exemplary embodiment.

### DETAILED DESCRIPTION

Embodiments will be described more fully hereinafter with reference to the accompanying drawings. As those skilled in the art would realize, the described embodiments may be modified in various different ways.

In the specification, unless explicitly described to the contrary, the word “comprise” and variations such as “comprises” or “comprising”, will be understood to imply the inclusion of stated elements but not the exclusion of any other elements. Further, in the specification, it will be understood that when an element such as a layer, film, region, or substrate is referred to as being “on” another element, it can be directly on the other element or intervening elements may also be present. Further, the word “on” means positioning on or below the object portion, but does not essentially mean positioning on the upper side of the object portion based on a gravity direction.

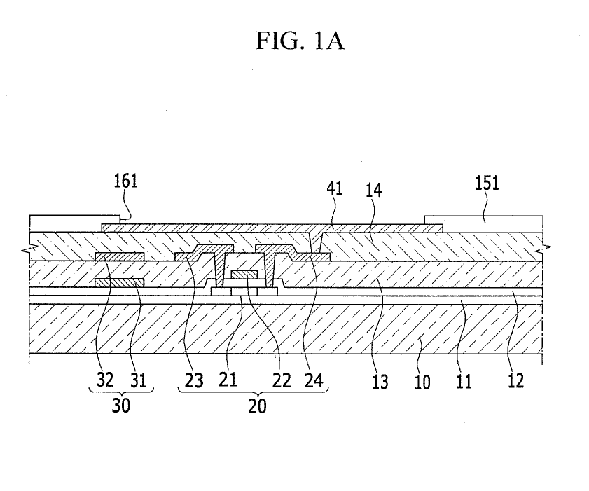

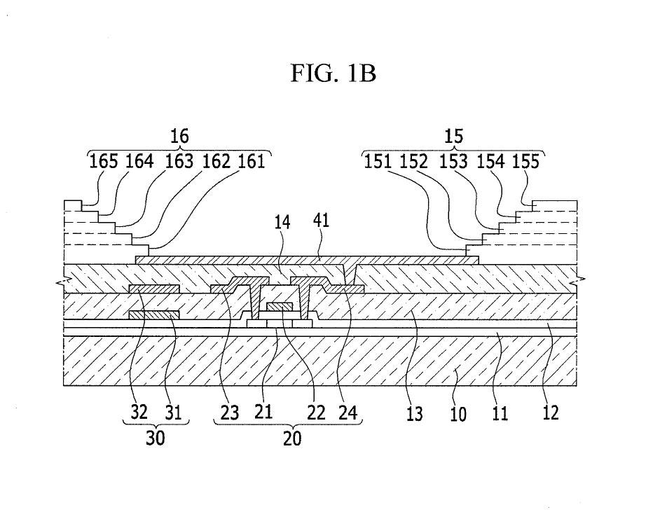

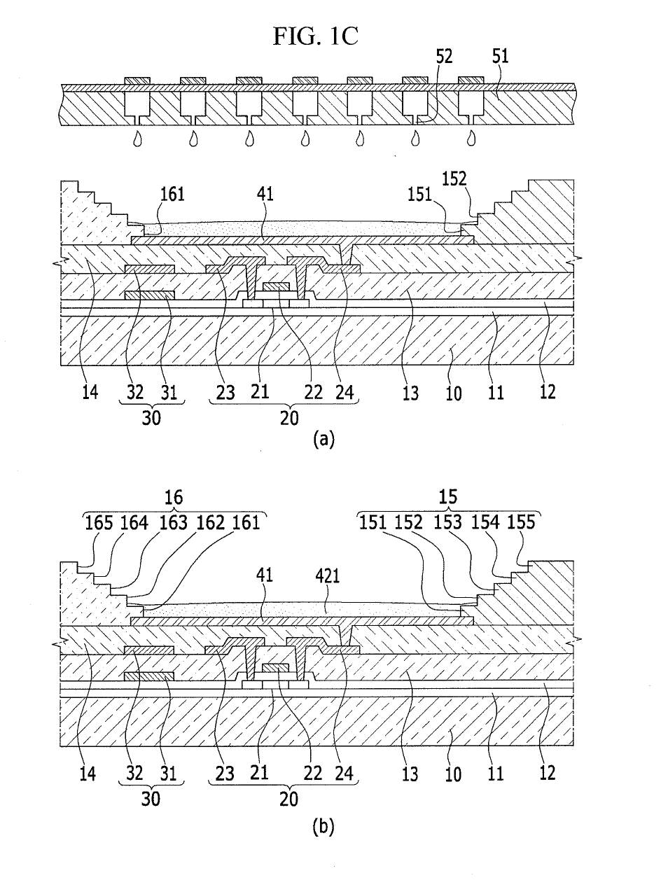

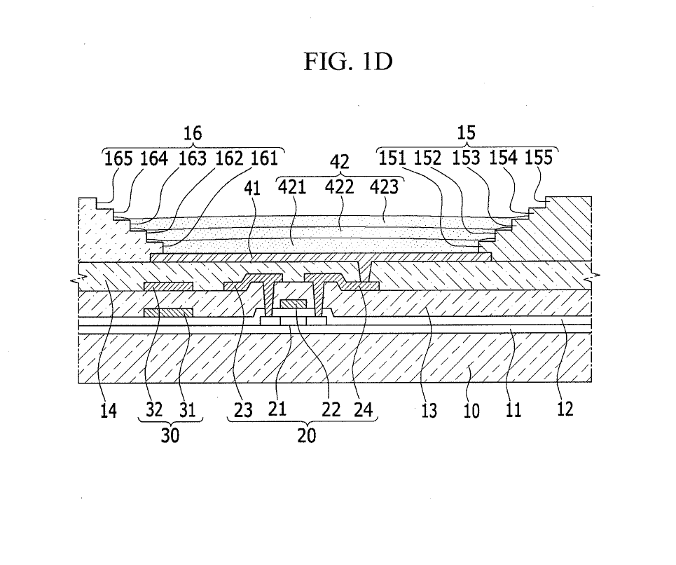

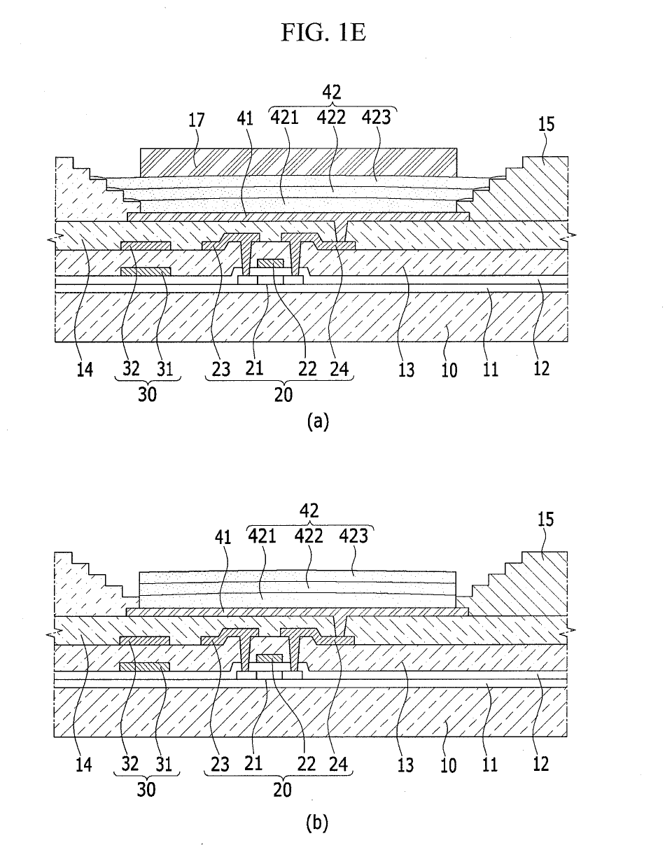

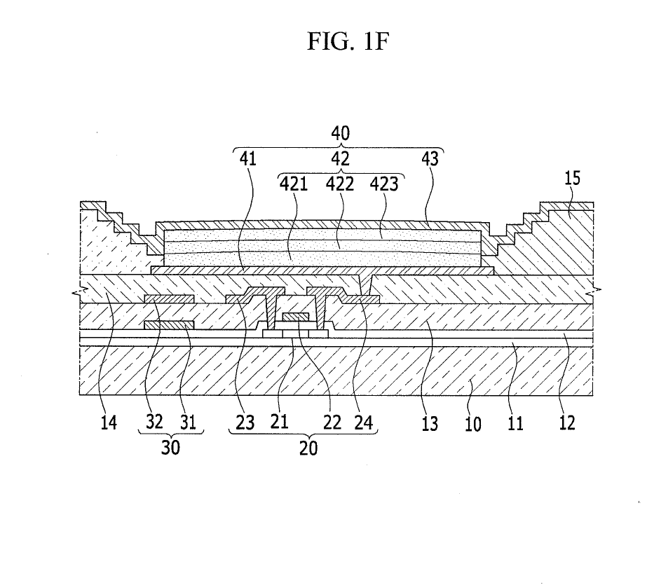

FIGS. 1A to 1F are cross-sectional views sequentially illustrating a manufacturing method of an OLED display according to a first exemplary embodiment. In FIGS. 1A to 1F, one pixel is illustrated, and a plurality of pixels is included on a substrate.

Referring to FIG. 1A, a buffer layer 11 is formed on a substrate 10, and a thin film transistor 20, a capacitor 30, and a pixel electrode 41 are formed over the buffer layer 11.

The substrate 10 may be a rigid substrate such as glass or a flexible substrate such as a polymer film. Since the polymer film has a higher moisture transmission rate and higher oxygen transmittance than the glass, when the substrate 10 is formed of the polymer film, a barrier layer for suppressing penetration of moisture and oxygen may be positioned between the substrate 10 and the buffer layer 11.

In some embodiments, the buffer layer 11 is formed as an inorganic layer, and for example, may include SiO₂ or SiNx. The buffer layer 11 provides a substantially flat surface for forming the pixel circuit and suppresses moisture and foreign particles from penetrating into the pixel circuit and the organic light emitting diode.

The thin film transistor 20 includes a semiconductor layer 21, a gate electrode 22, and source/drain electrodes 23 and 24. In some embodiments, the semiconductor layer 21 is formed of polysilicon or an oxide semiconductor, and includes a channel area in which impurities are not doped and a source/drain area in which impurities are doped at both sides of the channel area. When the semiconductor layer 21 is formed of the oxide semiconductor, a separate protective layer for protecting the semiconductor layer 21 may be added.

A gate insulating layer 12 is positioned between the semiconductor layer 21 and the gate electrode 22, and an interlayer insulating layer 13 is positioned between the gate electrode 22 and the source/drain electrodes 23 and 24. The capacitor 30 includes a first capacitive plate 31 formed on the gate insulating layer 12, and a second capacitive plate 32 formed on the interlayer insulating layer 13. The first capacitive plate 31 may be made of the same material as the gate electrode 22, and the second capacitive plate 32 may be made of the same material as the source/drain electrodes 23 and 24. The second capacitive plate 32 may be connected to the source electrode 23.

The thin film transistor 20 illustrated in FIG. 1A is a driving thin film transistor, and the pixel circuit further includes a switching thin film transistor (not illustrated). The switching thin film transistor is used as a switching element selecting a pixel to emit light, and the driving thin film transistor applies power for emitting the light of the selected pixel to the corresponding pixel.

A planarization layer 14 is positioned on the source/drain electrodes 23 and 24 and the second capacitive plate 32. The planarization layer 14 may be formed of at least one of an organic material and an inorganic material. The planarization layer 14 forms a via hole exposing a part of the drain electrode 24, and a pixel electrode 41 is formed on the planarization layer 14. The pixel electrode 41 is separately formed for each pixel, and connected with the drain electrode 24 of the thin film transistor 20 through the via hole.

The configuration of the thin film transistor 20 and the capacitor 30 illustrated in FIG. 1A is just exemplified, and the OLED display of the first exemplary embodiment is not limited to the illustrated example.

The pixel electrode 41 may be formed as a transparent conductive layer or a semi-transmitting layer, or formed as a reflective layer. The transparent conductive layer may include one of ITO, In₂O₃, IZO, and ZnO, and the semi-transmitting layer may be configured as a laminated layer of the transparent conductive layer and a metal thin film including silver (Ag), aluminum (Al), magnesium (Mg), and the like. The reflective layer may be formed of metal such as silver (Ag), aluminum (Al), magnesium (Mg), nickel (Ni), or chromium (Cr).

A first opening 161 exposing the pixel electrode 41 is formed by forming an insulation layer on the planarization layer 14 and the pixel electrode 41 and patterning the insulation layer through a known photolithography process. The insulation layer may be formed of an organic material such as polyimide, but is not necessarily limited to the organic material. The insulation layer having the first opening 161 becomes a first layer 151 of the pixel defining layer, and a side wall of the first opening 161 may be substantially perpendicular to, for example, the pixel electrode 41 due to a small thickness of the first layer 151.

Referring to FIG. 1B, a second opening 162 exposing a part of an upper surface of the first layer 151 in addition to the first opening 161 is formed by forming the insulation layer on the first layer 151 and patterning the insulation layer through a photolithography process. That is, the width of the second opening 162 is larger than the width of the first opening 161, and the insulation layer having the second opening 162 becomes a second layer 152 of the pixel defining layer 15. Further, a side wall of the second opening 162 may be substantially perpendicular to, for example, the pixel electrode 41 due to a small thickness of the second layer 152.

A third layer 153 of the pixel defining layer 15 having a third opening 163, a fourth layer 154 of the pixel defining layer 15 having a fourth opening 164, and a fifth layer 155 of the pixel defining layer 15 having a fifth opening 165 are sequentially formed by repetitively forming and patterning the insulation layer. Further, a side wall of the third opening 163, a side wall of the fourth opening 164, and a side wall of the fifth opening 165 may be substantially perpendicular to, for example, the pixel electrode 41.

The third opening 163 exposes a part of an upper surface of the second layer 152 along with the second opening 162, and the fourth opening 164 exposes a part of an upper surface of the third layer 153 along with the third opening 163. That is, an opening of a later formed layer has a larger width, and the later formed layer exposes a part of an upper surface of a previous layer along with an opening of the previous layer.

In FIG. 1B, the pixel defining layer 15 constituted by five layers is illustrated as an example, but the number of pixel defining layers 15 is not limited to the illustrated example. The first to fifth layers 151 to 155 may be formed of the same insulating material, or at least one layer may be formed of a different insulating material from an adjacent layer.

The first to fifth layers 151 to 155 may have substantially the same thickness. In addition, each of the first to fifth layers 151 to 155 has a smaller thickness than one organic emission layer formed by a printing method to be described below. The side wall of the opening 16 of the pixel defining layer 15 may be formed in a step shape by the above described process, and the pixel defining layer 15 is formed by laminating the plurality of layers 151 to 155 having small thicknesses.

That is, the pixel defining layer 15 does not have a side wall of the opening having a single slope, but has the side wall of the opening 16 having the step shape by sequentially laminating the layers 151 to 155 having small thicknesses. Each layer configuring the pixel defining layer serves to uniformize the thickness of each layer configuring the organic emission layer.

Referring to FIG. 1C, a first layer 151 of the organic emission layer is formed by ejecting a solution (hereinafter, referred to as a ‘printing solution’ for convenience) including an organic material and a solvent into the first opening 161 of the pixel defining layer 15 by using a known printing method and evaporating and drying the solvent. The printing method is a method of storing the printing solution in the ejecting head 51 and ejecting the droplets of the printing solution on the pixel electrode 41 through nozzles 52 installed in the ejecting head 51.

The thickness of the first layer 151 of the pixel defining layer 15 may be smaller than the thickness of the printing solution ejected from the nozzles 52. Accordingly, the ejected printing solution may fill the first opening 161 of the pixel defining layer 15 at a regular thickness, and cover the upper surface of the first layer 151 along an edge. In this case, the thickness of the ejected printing solution does not exceed a height of the second layer 152.

The printing solution ejected from the ejecting head 51 may be substantially uniformly distributed at a small thickness in the first opening 161 of the pixel defining layer 15, and as a result, the solvent may be evaporated at the central portion and the edge of the ejected printing solution under substantially the same condition. As a result, the first layer 421 of the organic emission layer which is completed after the solvent is evaporated and dried may have a uniform thickness.

The printing solution ejected from the nozzles 52 may have an entirely upward convex shape by surface tension, and the first layer 421 after the solvent is evaporated and dried may also have a substantially entirely upward convex shape. However, the shape of the first layer 421 is not limited to the illustrated example.

Referring to FIG. 1D, the second layer 422 of the organic emission layer 42 is formed by ejecting the printing solution in the second opening 162 of the pixel defining layer 15 on the first layer 421 of the organic emission layer 42 and evaporating and drying the solvent. Accordingly, the ejected printing solution may fill the second opening 162 of the pixel defining layer 15 at a regular thickness, and cover the upper surface of the second layer 152 along an edge. In this case, the thickness of the ejected printing solution does not exceed the height of the third layer 153.

The printing solution is substantially uniformly distributed with a small thickness in the second opening 162 of the pixel defining layer 15, and accordingly, the solvent is substantially uniformly evaporated and thus the second layer 422 of the organic emission layer 42 may have also a uniform thickness.

In some embodiments, the third layer 423 of the organic emission layer 42 is formed by repetitively ejecting the printing solution and evaporating the solvent. The second layer 422 of the organic emission layer 42 may be formed to have a larger width than the first layer 421, and the third layer 423 may be formed to have a larger width than the second layer 422. That is, a later formed layer may be formed to have a larger width than an earlier formed layer. In FIG. 1D, the organic emission layer 42 configured by the three layers 421, 422, and 423 is illustrated as an example, but the number of organic emission layers 42 is not limited to the illustrated example.

Meanwhile, the first layer 421 of the organic emission layer 42 may have a convexly protruding edge on the first layer 151 of the pixel defining layer 15, and the second layer 422 and the third layer 423 may also have convexly protruding edges on the second layer 152 and the third layer 153 of the pixel defining layer 15. However, since the edge is a portion removed by etching to be described below, the edge does not influence the thickness uniformity of the organic emission layer 42.

The organic emission layer 42 is configured by a plurality of layers corresponding to at least two layers among the layers 151 to 155 configuring the pixel defining layer 15. In some embodiments, the heights of the upper surfaces of the layers 421, 422, and 423 configuring the organic emission layer 42 are larger than heights of the layers 151, 152, and 153 of the pixel defining layer 15 corresponding to the heights of the upper surfaces.

In this case, the number of layers 421 to 423 configuring the organic emission layer 42 may be smaller than the number of layers 151 to 155 configuring the pixel defining layer 15, and the entire height of the organic emission layer 42 is smaller than a depth of the opening 16 of the pixel defining layer 15.

The layers 421, 422, and 423 configuring the organic emission layer 42 have excellent thickness uniformity, and the organic emission layer 42 with the layers laminated also has entirely excellent thickness uniformity. The layers 421, 422, and 423 configuring the organic emission layer 42 may have the same thickness.

Referring to FIG. 1E, a mask layer 17 having a smaller width than the organic emission layer 42 is formed on the organic emission layer 42, and an outer portion of the organic emission layer 42 which is not covered by the mask layer 17 is removed by etching. The mask layer 17 may be a photoresist layer.

In some embodiments, the width of the mask layer 17 is substantially the same as or larger than the width of the first opening 161 of the pixel defining layer 15. In these embodiments, the entire organic emission layer 42 has substantially the same width as or a larger width than the first opening 161 of the pixel defining layer 15. When the organic emission layer 42 has a smaller width than the first opening 161 of the pixel defining layer 15, a common electrode to be subsequently formed contacts the pixel electrode 41.

An emission area of the pixel corresponding to the organic emission layer 42 may be limited to the central portion of the pixel, by removing the outer portion of the organic emission layer 42. The organic emission layer 42 may display one of red, green, and blue or display white. A white organic emission layer may be configured by a laminated layer of a red emission layer, a green emission layer, and a blue emission layer. The color of the organic emission layer 42 is not limited to the above example.

Referring to FIG. 1F, a common electrode 43 is formed on the organic emission layer 42 and the pixel defining layer 15. The common electrode 43 is formed at every one of the pixels, and may be formed as a transparent conductive layer or a semi-transmitting layer, or formed as a reflective layer. The pixel electrode 41, the organic emission layer 42, and the common electrode 43 configure the OLED 40.

One of the pixel electrode 41 and the common electrode 43 is an anode which is a hole injection electrode, and the other is a cathode which is an electron injection electrode. A hole injected from the anode and an electron injected from the cathode are coupled with each other in the organic emission layer 42 to generate an exciton, and while the exciton emits energy, light is emitted.

At least one of a hole injection layer and a hole transport layer may be positioned between the anode and the organic emission layer 42, and at least one of an electron injection layer and an electron transport layer may be positioned between the cathode and the organic emission layer 42. The hole injection layer, the hole transport layer, the electron transport layer, and the electron injection layer may be formed at all the plurality of pixels.

One of the pixel electrode 41 and the common electrode 43 may be formed as a reflective layer, and the other may be formed as a semi-transmitting layer or a transparent conductive layer. The light emitted from the organic emission layer 42 is reflected from the reflective layer and passes through the semi-transmitting layer or the transparent conductive layer to be emitted outside. In the case of the semi-transmitting layer, a part of the light emitted from the organic emission layer 42 is reflected again to the reflective layer to form a resonance structure.

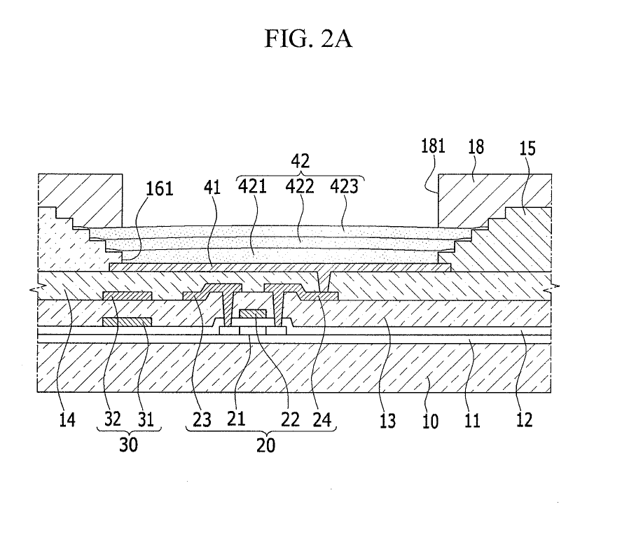

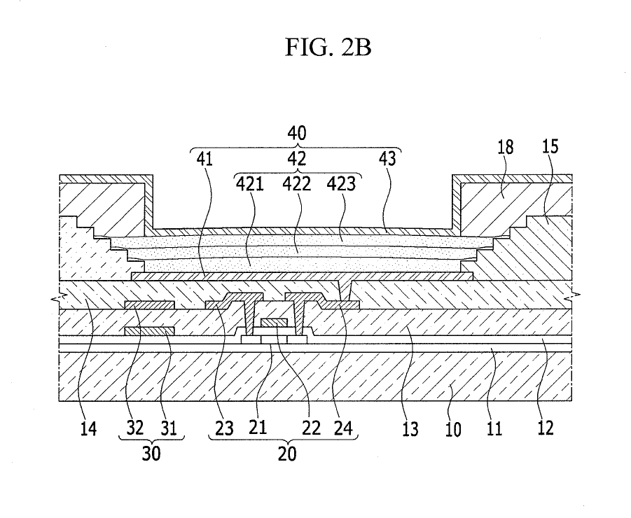

FIGS. 2A and 2B are cross-sectional views sequentially illustrating a manufacturing method of an OLED display according to a second exemplary embodiment.

Referring to FIG. 2A, a process of forming the buffer layer 11, the thin film transistor 20, the capacitor 30, the pixel electrode 41, the pixel defining layer 15, and the organic emission layer 42 on the substrate 10 is the same as that of the first exemplary embodiment described above. However, differently from the first exemplary embodiment, an outer portion of the organic emission layer 42 is not removed by etching, and a light blocking layer 18 is formed on the outer portion of the organic emission layer 42.

The light blocking layer 18 is formed on the outer portion of the organic emission layer 42 and the pixel defining layer 15. That is, the light blocking layer 18 has an opening 181 exposing a central portion of the organic emission layer 42. The opening 181 of the light blocking layer 18 may have substantially the same width as the first opening 161 of the pixel defining layer 15. The light blocking layer 18 blocks the light generated from the outer portion of the organic emission layer 42 and thus an emission area of the pixel is limited to the central portion of the organic emission layer 42.

Referring to FIG. 2B, a common electrode 43 is formed on the light blocking layer 18 and the organic emission layer 42. The common electrode 43 is formed in each of the pixels, and contacts the organic emission layer 42 at the opening 181 of the light blocking layer 18. The common electrode 43 may be formed as a transparent conductive layer or a semi-transmitting layer, or formed as a reflective layer. The pixel electrode 41, the organic emission layer 42, and the common electrode 43 configure the OLED 40.

In the OLED displays of the first exemplary embodiment and the second exemplary embodiment described above, the thickness uniformity of the organic emission layer 42 formed by the printing method may be increased by the pixel defining layer 15 having the above shape. That is, the printing solution ejected from the nozzles 52 is substantially uniformly distributed with a small thickness in the openings 161 to 165 formed in the layers 151 to 155 of the pixel defining layer 15, and as a result, excellent thickness uniformity may be secured by inducing uniform evaporation of the solvent.

Accordingly, the OLED displays of the first exemplary embodiment and the second exemplary embodiment are suitable for mass production, and it is possible to improve a display characteristic by increasing light emission uniformity of each pixel. Further, since there is no large modification in other constituent elements except for the pixel defining layer 15 as compared with a manufacturing process in the related art, it is possible to easily manufacture the OLED display by using existing manufacturing equipment.

While this disclosure has been described in connection with certain exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode display, comprising:
a pixel electrode formed over a substrate;
a pixel defining layer formed over the pixel electrode, the pixel defining layer having an opening and a stepped side wall of the opening, wherein the pixel defining layer is formed only on a peripheral region of the pixel electrode which is located outside the opening;
an organic emission layer formed over the pixel electrode in the opening of the pixel defining layer; and
a common electrode covering the organic emission layer and the pixel defining layer.

2. The display of claim 1, wherein the pixel defining layer comprises a plurality of layers having openings which have different widths, and wherein the widths of the openings become larger as the layers are farther from the pixel electrode.

3. The display of claim 2, wherein the layers are formed of the same insulating material, and have substantially the same thickness.

4. The display of claim 2, wherein the organic emission layer comprises a plurality of layers corresponding to at least two of the layers of the pixel defining layer.

5. The display of claim 4, wherein the thickness of each of the layers of the pixel defining layer is smaller than the thickness of each of the layers of the organic emission layer.

6. The display of claim 4, wherein the pixel defining layer includes a first layer having a first opening, and a second layer formed on the first layer and having a second opening, and
wherein the organic emission layer includes a first layer which has a greater height than the first layer of the pixel defining layer, and a second layer which has a greater height than the second layer of the pixel defining layer.

7. The display of claim 6, wherein the organic emission layer has substantially the same width as the first opening.

8. The display of claim 4, wherein the pixel defining layer includes a first layer having a first opening, and a second layer formed on the first layer and having a second opening, and
wherein the organic emission layer includes a first layer substantially filling the first opening of the pixel defining layer and covering the first layer of the pixel defining layer, and a second layer substantially filling the second opening of the pixel defining layer and covering the second layer of the pixel defining layer.

9. The display of claim 8, further comprising:
a light blocking layer directly formed on the organic emission layer and the pixel defining layer,
wherein the light blocking layer has an opening which is located substantially directly above a central portion of the organic emission layer.

10. The display of claim 1, wherein the common electrode comprises a peripheral portion which covers the stepped side wall of the opening.

11. The display of claim 10, wherein the peripheral portion of the common electrode has a shape corresponding to the stepped side wall of the opening.

12. A method of manufacturing an organic light emitting diode display, comprising:
forming a pixel circuit over a substrate;
forming a planarization layer to cover the pixel circuit;
forming a pixel electrode over the planarization layer;
laminating first, second and third layers over the pixel electrode so as to form a pixel defining layer, wherein the first layer has a first opening, wherein the second layer has a second opening larger than the first opening, and wherein the third layer has a third opening larger than the second opening;
ejecting a printing solution into the first opening and then evaporating a solvent so as to form a first layer of the organic emission layer;
ejecting the printing solution into the second opening and evaporating the solvent so as to form a second layer of the organic emission layer; and
forming a common electrode over the organic emission layer and the pixel defining layer.

13. The method of claim 12, wherein a side wall of the first opening, a side wall of the second opening, and a side wall of the third opening are substantially perpendicular to the pixel electrode, and
wherein the first layer, the second layer, and the third layer of the pixel defining layer have substantially the same thickness.

14. The method of claim 12, wherein the printing solution ejected into the first opening covers the first layer of the pixel defining layer along an edge, and
wherein the printing solution ejected into the second opening covers the second layer of the pixel defining layer along an edge.

15. The method of claim 14, further comprising:
removing an outer portion of the organic emission layer via etching before forming the common electrode.

16. The method claim 15, wherein the width of the organic emission layer is substantially the same as or larger than the width of the first opening of the pixel defining layer.

17. The method claim 14, further comprising:
forming a light blocking layer over the organic emission layer and the pixel defining layer before forming the common electrode,
wherein the light blocking layer has an opening which is substantially directly above a central portion of the organic emission layer.

18. The method of claim 17, wherein the width of the opening of the light blocking layer is substantially the same as the width of the first opening.

19. An organic light emitting diode display, comprising:
a pixel electrode formed over a substrate;
a pixel defining layer formed over the pixel electrode, the pixel defining layer having an opening and a stepped side wall of the opening, wherein the opening is located substantially directly above a central portion of the pixel electrode;
an organic emission layer formed over the pixel electrode in the opening of the pixel defining layer; and
a common electrode covering the organic emission layer and the stepped side wall of the pixel defining layer.

20. The display of claim 19, wherein the common electrode comprises a peripheral portion which covers and has a shape corresponding to the stepped side wall of the opening.
